(19) United States
(12) Patent Application Publication
(10) Pub. No.: US 2013/0188085 A1
(43) Pub. Date: Jul. 25, 2013

(54) IMAGE SENSORS HAVING REDUCED DARK CURRENT AND IMAGING DEVICES HAVING THE SAME

(71) Applicants: Eun Sub Shim, Anyang-si (KR); Moo Sup Lim, Yongin-si (KR); Seung Sik Kim, Hwaseong-si (KR); Jung Chak Ahn, Yongin-si (KR)

(72) Inventors: Eun Sub Shim, Anyang-si (KR); Moo Sup Lim, Yongin-si (KR); Seung Sik Kim, Hwaseong-si (KR); Jung Chak Ahn, Yongin-si (KR)

(73) Assignee: Samsung Electronics Co.Ltd

(21) Appl. No.: 13/616,306

(22) Filed: Sep. 14, 2012

(30) Foreign Application Priority Data
Jan. 19, 2012 (KR) 10-2012-0006045

(51) Int. Cl. H04N 5/222; H01L 27/146

(52) U.S. Cl. 348/333.08; 250/214 R; 348/E05.022

(57) ABSTRACT

An image sensor includes a photo detector for accumulating charges in response to an incident light, a floating diffusion node, a first reset unit connected between a supply voltage node and the floating diffusion node, a transmission unit for transmitting accumulated charges from the photo detector to the floating diffusion node, a source follower output unit for converting charges stored in the floating diffusion node into an output voltage, a first selection unit for outputting the output voltage selectively, and a second selection unit connected between the floating diffusion node and the source follower output unit. Dark current may be reduced or prevented from flowing from the source follower output unit into the floating diffusion node.

### CROSS-REFERENCE TO RELATED APPLICATION

This application claims priority under 35 U.S.C. §119(a) from Korean Patent Application No. 10-2012-0006045 filed on Jan. 19, 2012, the disclosure of which is hereby incorporated by reference in its entirety.

### BACKGROUND

Various embodiments described herein relate to sensors, and more particularly, to image sensors and image devices having the same.

An image sensor is a device that converts an optical image into an electrical signal. The image sensor is used in a digital camera or other image processing devices.

The image sensor generally reads an image by line. Accordingly, there is generally a time lag between lines. When the image sensor captures a fast moving object, there may be distortion in a captured image due to the time lag. To reduce or prevent the distortion, an electronic shutter may be used. The electronic shutter exposes an image sensor to light at the same rate as a frame interval or at a faster rate without using a mechanical shutter.

A dark current may be generated even though the image sensor is not exposed to light. The dark current may increase noise of an image output from the image sensor.

### SUMMARY

Various embodiments described herein are directed to an image sensor, including a photo detector configured to accumulate charges in response to an incident light, a floating diffusion node, a first reset unit responsive to a first reset gate signal, and which is connected between a supply voltage node and the floating diffusion node, a transmission unit configured to transmit charges accumulated by the photo detector to the floating diffusion node in response to a transmission gate signal, an output unit such as a source follower output unit configured to convert charges stored in the floating diffusion node into an output voltage, a first selection unit configured to output the output voltage selectively in response to a first selection gate signal, and a second selection unit responsive to a second selection gate signal and which is connected between the floating diffusion node and the output unit.

The image sensor further includes a row driver configured to output the first reset gate signal, the transmission gate signal, the first selection gate signal and the second selection gate signal.

A phase of the first selection gate signal and a phase of the second selection gate signal may be the same.

According to other embodiments, a phase of the first selection gate signal leads a phase of the second selection gate signal.

According to other embodiments, the image sensor may further include a second reset unit connected between the power voltage node and the output unit.

In some embodiments, the row driver is further configured to output a second reset gate signal having a low level to control the second reset unit when each of the first selection gate signal and the second selection gate signal has a high level.

According to other embodiments, the image sensor may further include an overflow unit connected between the supply voltage node and the photo detector to reduce or prevent the charges from flowing over the photo detector.

The row driver may be further configured to output an overflow gate signal having a high level to reduce or prevent the charges from flowing over the photo detector.

Various embodiments described herein may also be directed to an imaging device, which may be portable, and which includes the image sensor and a display displaying data processed by the image sensor.

An image sensor according to various other embodiments described herein includes a photo detector configured to accumulate charges in response to incident light; a floating diffusion region; a reset unit responsive to a first reset gate signal, and which is connected between a supply voltage node and the floating diffusion region; a transmission unit configured to transmit accumulated charges from the photo detector to the floating diffusion region in response to a transmission gate signal; and an output unit such as a source follower output unit configured to convert charges stored in the floating diffusion region into an output voltage. A selection unit is also provided, which is connected between the floating diffusion region and the output unit, and is configured to reduce dark current that flows into the floating diffusion region, compared to absence of the selection unit between the floating diffusion region and the output unit. In some embodiments, the selection unit is configured to prevent dark current from flowing into the floating diffusion region. In other embodiments, an overflow unit is also provided, which is connected between the supply voltage node and the photo detector and is configured to reduce or prevent the charges from flowing over the photo detector. The image sensor may be combined with a signal processor configured to process image data from the image sensor. The image sensor may be further combined with a display that is configured to display the image data that is processed.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of an image processing device according to an example embodiment of the present inventive concepts;

FIG. 2 is a circuit diagram depicting an example embodiment of a pixel embodied in a pixel array illustrated in FIG. 1;

FIG. 3 is a cross-sectional diagram of the pixel illustrated in FIG. 2;

FIG. 4 is a top view of the pixel illustrated in FIG. 2;

FIG. 5 is a timing diagram of control signals for explaining an example embodiment of an operation of the pixel illustrated in FIG. 2;

FIG. 6 is a timing diagram of control signals for explaining another example embodiment of the operation of the pixel illustrated in FIG. 2;

FIG. 7 is a timing diagram of control signals for explaining still another example embodiment of the operation of the pixel illustrated in FIG. 2;

FIG. 8 is a circuit diagram depicting another example embodiment of the pixel embodied in the pixel array illustrated in FIG. 1;

FIG. 9 is a timing diagram of control signals for explaining an example embodiment of an operation of a pixel illustrated in FIG. 8;

FIG. 10 is a timing diagram of the control signals for explaining another example embodiment of the operation of the pixel illustrated in FIG. 8;

FIG. 11 is a timing diagram of the control signals for explaining still another example embodiment of the operation of the pixel illustrated in FIG. 8;

FIG. 12 is a timing diagram of the control signals for explaining still another example embodiment of the operation of the pixel illustrated in FIG. 8;

FIG. 13 is a timing diagram of the control signals for explaining still another example embodiment of the operation of the pixel illustrated in FIG. 8;

FIG. 14 is a timing diagram of the control signals for explaining still another example embodiment of the operation of the pixel illustrated in FIG. 8;

FIG. 15 is a circuit diagram depicting still another example embodiment of the pixel embodied in the pixel array illustrated in FIG. 1;

FIG. 16 is a cross-sectional diagram of the pixel illustrated in FIG. 15;

FIG. 17 is a top view of the pixel illustrated in FIG. 15;

FIG. 18 is a timing diagram of control signals for explaining an example embodiment of an operation of the pixel illustrated in FIG. 15;

FIG. 19 is a timing diagram of control signals for explaining another example embodiment of the operation of the pixel illustrated in FIG. 15;

FIG. 20 is a circuit diagram depicting still another example embodiment of the pixel embodied in the pixel array illustrated in FIG. 1;

FIG. 21 is a timing diagram of control signals for explaining an example embodiment of the operation of the pixel illustrated in FIG. 20;

FIG. 22 is a timing diagram of control signals for explaining another example embodiment of the operation of the pixel illustrated in FIG. 20;

FIG. 23 is a timing diagram of control signals for explaining still another example embodiment of the operation of the pixel illustrated in FIG. 20;

FIG. 24 is a timing diagram of control signals for explaining still another example embodiment of the pixel illustrated in FIG. 20; and

FIG. 25 is a block diagram depicting another example embodiment of the image processing device including the pixel illustrated in FIG. 2, 8, 15 or 20.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Moreover, the functionality of a given block of the block diagrams may be separated into multiple blocks and/or the functionality of two or more blocks of the block diagrams may be at least partially integrated. Finally, other blocks may be added/inserted between the blocks that are illustrated.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

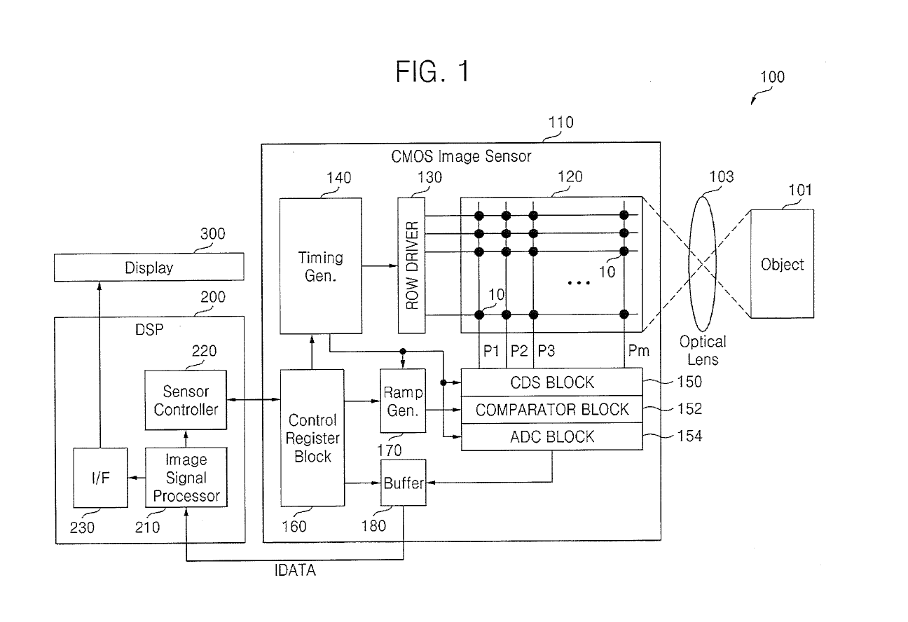

FIG. 1 is a block diagram of an image processing device, also referred to as an “imaging device”, according to an example embodiment of the present inventive concepts. Referring to FIG. 1, an image processing device 100 may be embodied in a portable device. The portable device may be embodied in a digital camera, a mobile phone, a smart phone or a tablet personal computer (PC). The image processing device may also be embodied in a non-portable device, such as a desktop PC or a security camera.

The image processing device 100 includes an optical lens 103, an image sensor 110, a digital signal processor (DSP) 200 and a display 300.

The image sensor 110 generates image data IDATA for a photographed or captured object 101 through the optical lens 103. For example, the image sensor 110 may be embodied in a CMOS image sensor.

The image sensor 110 includes a pixel array 120, a row driver 13, a timing generator 140, a correlated double sampling (CDS) block 150, a comparator block 152, an analog to digital conversion (ADC) block 154, a control register block 160, a ramp signal generator 170 and a buffer 180.

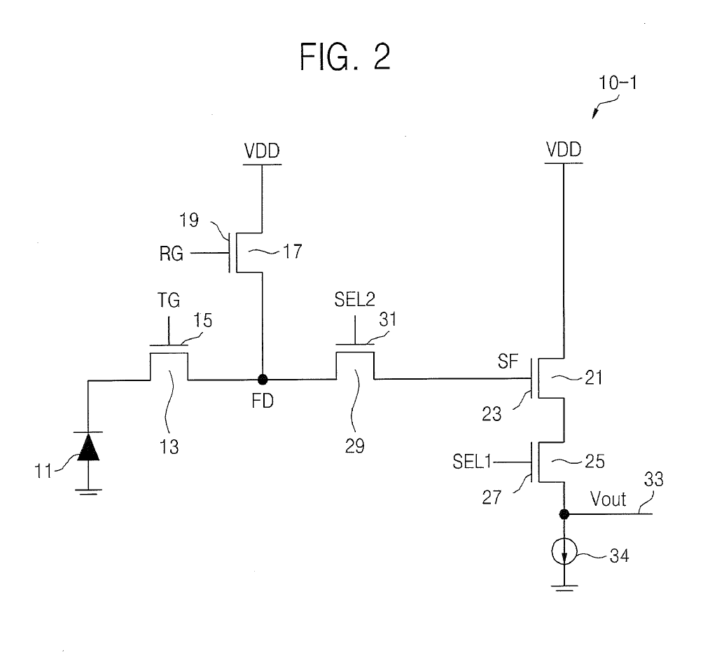

A pixel array 120 includes a plurality of pixels 10 arranged in a form of matrix. A structure and an operation of each of the plurality of pixels 10 will be explained in detail referring to FIGS. 2 to 24.

A row driver 130 drives a plurality of control signals for controlling an operation of each of the plurality of pixels 10 to the pixel array 120 according to a control of a timing generator 140. The timing generator 140 controls an operation of the row driver 130, the CDS block 150, the ADC block 154 and the ramp signal generator 170 according to a control of the control register block 160.

The CDS block 150 performs a correlated double sampling on each pixel signal P1 to Pm, where m is a natural number, output from each of a plurality of column lines embodied in the pixel array 120. The comparator block 152 compares each of a plurality of correlated double sampled pixel signals output from the CDS block 150 with a ramp signal output from the ramp signal generator 170 and outputs a plurality of comparison signals.

The ADC block 154 converts each of the plurality of comparison signals output from the comparator block 152 into a digital signal and outputs a plurality of digital signals to the buffer 180. The control register block 160 controls an operation of the timing generator 140, the ramp signal generator 170 and the buffer 180 according to a control of a DSP 200. The buffer 180 transmits image data IDATA corresponding to a plurality of digital signals output from the ADC block 154 to the DSP 200.

The DSP 200 includes an image signal processor ISP 210, a sensor controller 220 and an interface 230.

The ISP 210 controls the sensor controller 220, which controls the control register block 160, and the interface 210. According to an example embodiment, the image sensor 110 and the DSP 200 may be embodied in a single package, e.g., a multi-chip package. According to another example embodiment, the image sensor 110 and the ISP 210 may be embodied in a single package, e.g., a multi-chip package.

The ISP 210 processes image data IDATA transmitted from the buffer 180 and transmits processed image data to the interface 230. The sensor controller 220 generates various control signals for controlling the control register block 160 according to a control of the image signal processor 210. The interface 230 transmits image data processed by the image signal processor 210 to a display 300. The display 300 displays image data output from the interface 230. The display 300 may be embodied in a thin film transistor-liquid crystal display (FTF-LCD), a light emitting diode (LED) display, an organic LED (OLED) display, an active-matrix OLED (AMOLED) display and/or another type of display.

FIG. 2 is a circuit diagram depicting an example embodiment of a pixel embodied in the pixel array illustrated in FIG. 1. Referring to FIGS. 1 and 2, a pixel 10-1 according to an example embodiment of a pixel 10 includes a photo detector 11, a transmission transistor 13, a reset transistor 17, a source follower output transistor 21, a first selection transistor 25, a second selection transistor 29 and a current source 34.

The photo detector 11 accumulates charges in response to an incident light. The photo detector 11 may be embodied in a photo diode, a photo transistor, a pin photodiode and/or another type of photo detector.

The transmission transistor 13 is connected between the photo detector 11 and a floating diffusion node (FD). The transmission transistor 13 includes a transmission gate 15 controlling transmission of the charges to the floating diffusion node FD. The transmission transistor 13 is activated by a transmission gate signal TG. For example, the transmission gate signal TG is at a high level, the transmission transistor 13 transmits charges generated by the photo detector 11.

The reset transistor 17 is connected between a node supplying a supply voltage VDD and the floating diffusion node FD. The reset transistor 17 includes a reset gate 19 for resetting the photo detector 11 or the floating diffusion node FD. The reset transistor 17 is activated by a reset gate signal RG. For example, when the reset gate signal RG is at a high level, the reset transistor 17 may be activated.

The source follower output transistor 21 includes a source follower gate 23. The source follower output transistor 21 is activated by a source follower gate signal SF. The source follower output transistor 21 converts charges stored in the floating diffusion node FD into an output voltage Vout.

The first selection transistor 25 is connected between the source follower output transistor 21 and a current source 34. The first selection transistor 25 includes a first selection gate 27. The first selection gate 27 is used to output an output voltage Vout to a column line 33 in response to a first selection signal SEL1. For example, when the first selection signal SEL1 is at a high level, the first selection gate 27 outputs an output voltage Vout to the column line 33 as a pixel signal.

The second selection transistor 29 is connected between the floating diffusion node FD and the source follower gate 23. The second selection transistor 29 includes a second selection gate 31. The second selection transistor 29 is activated by a second selection gate signal SEL2. The current source 34 may operate as an active load. A plurality of control signals TG, RG, SEL1 and SEL2 are output from the row driver 130.

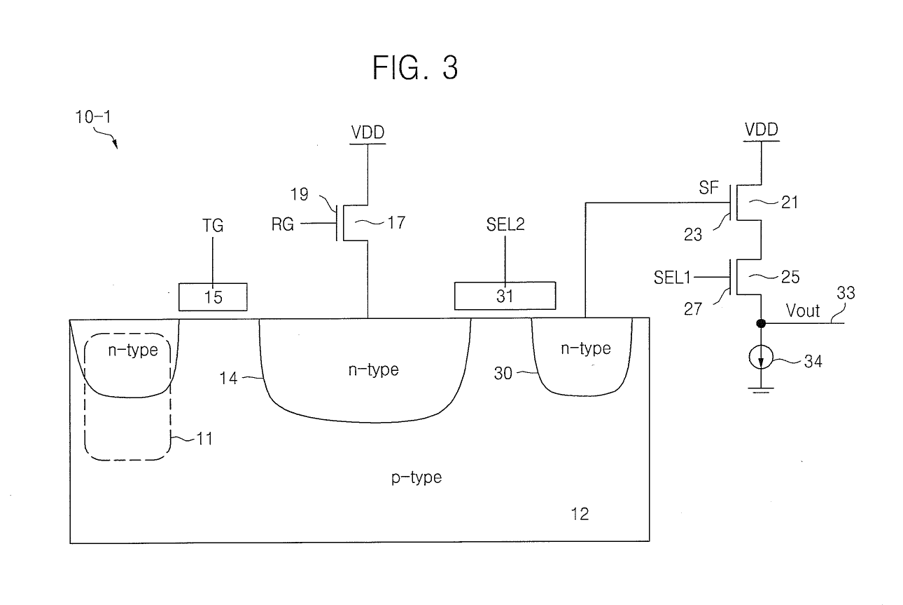

FIG. 3 is a cross-sectional diagram of the pixel illustrated in FIG. 2. Referring to FIGS. 2 and 3, each element 15, 19, 23, 27 and 31 may be arranged in and/or on a semiconductor substrate 12. The semiconductor substrate 12 may be a p-type epitaxial region in a single element and/or compound semiconductor substrate and/or a semiconductor layer.

The photo detector 11, the floating diffusion region 14 and an impurity region 30 may be formed by implanting a n-type dopant in the semiconductor substrate 12.

The photo detector 11 includes a n-type region and a p-type epitaxial region. The floating diffusion region 14 is a charge storage region of the floating diffusion node FD. The floating diffusion region 14 includes a n-type region.

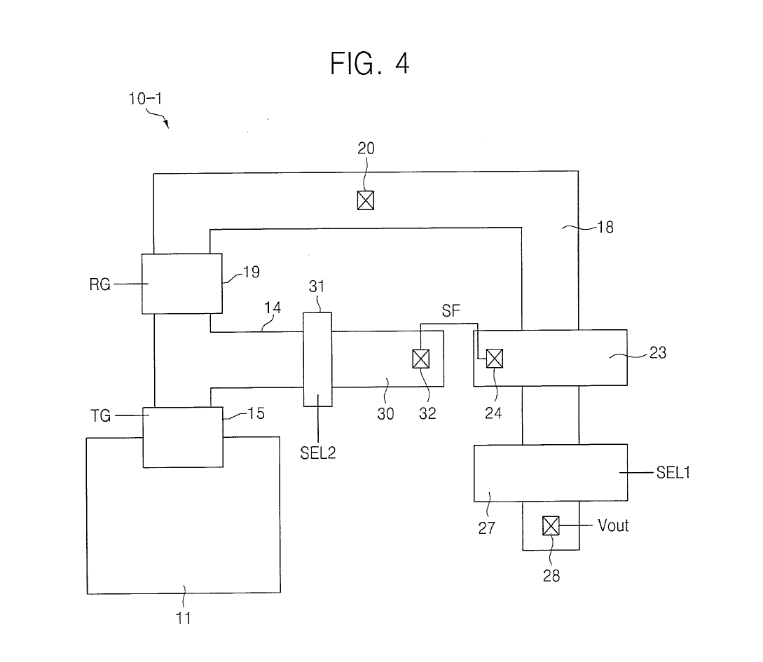

FIG. 4 is a top view of the pixel illustrated in FIG. 2. Referring to a layout illustrated in FIG. 4, the impurity region 30 includes a contact 32 for applying a source follower gate signal SF to the source follower gate 23. The contact 32 is connected to a source follower gate contact 24 of the source follower gate 23. The second selection gate 31 reduces or prevents a dark current generated by the contact 32 from flowing in the floating diffusion region 14 from the impurity region 30. A supply voltage region 18 includes a supply voltage contact 20 for receiving a supply voltage VDD. An output voltage Vout is output through an output voltage contact 28.

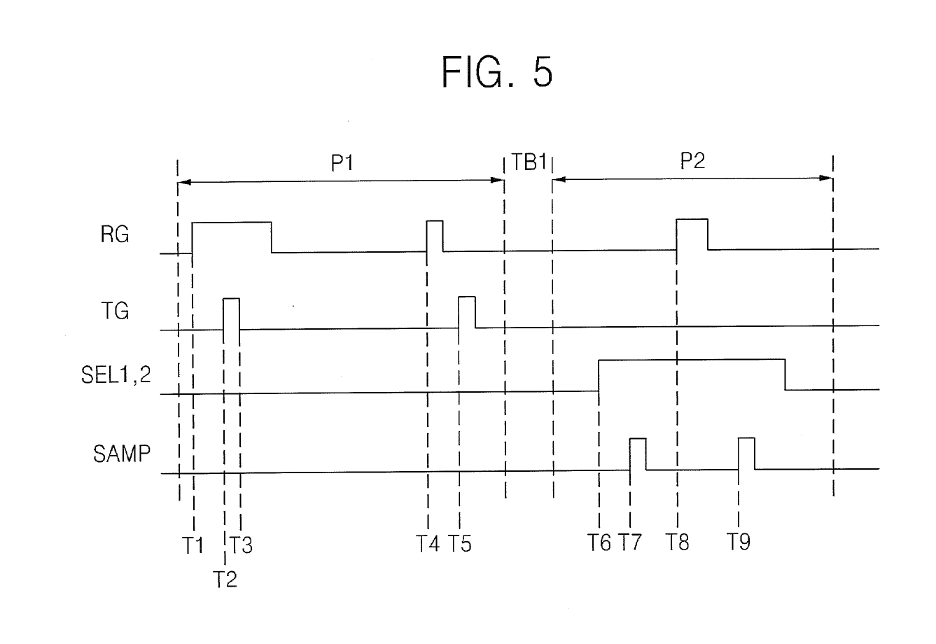

FIG. 5 is a timing diagram of control signals RG, TG, SEL1 and SEL2 for explaining an example embodiment of an operation of the pixel illustrated in FIG. 2. Referring to FIGS. 2 and 5, when a reset gate signal RG is applied to a reset gate 19 at a first time point T1, the floating diffusion node FD is reset to a supply voltage VDD.

When a reset gate signal RG is applied to the reset gate 19 and a transmission gate signal TG is applied to a transmission gate 15 at a second time point T2, the photo detector 11 is reset to a supply voltage VDD. The photo detector 11 accumulates charges in response to an incident light from a third time point T3 to a fifth time point T5. When a reset gate signal RG is applied to the reset gate 19 at a fourth time point T4, the floating diffusion node FD is reset to a supply voltage VDD.

When a transmission gate signal TG is applied to a transmission gate 15 at a fifth time point 15, accumulated charges are transmitted to the floating diffusion node FD from the photo detector 11. When a first selection signal SEL1 is applied to the first selection gate 27 at a sixth time point T6 and a second selection signal SEL2 is applied to the second selection gate 31, the source follower output transistor 21 converts charges stored in the floating diffusion node FD into an output voltage Vout. A pixel signal SAMP having a signal level at a seventh time point T7 is output to a column line 33. The signal level is a level corresponding to a level of an output voltage Vout.

When a reset gate signal RG having a high level is applied to the reset gate 19 at an eighth time point T8, the source follower output transistor 21 converts a supply voltage VDD into an output voltage Vout. A pixel signal SAMP having a reset level at a ninth time point T9 is output to the column line 33. The reset level is a level corresponding to a level of an output voltage Vout.

When the pixel signal SAMP is output it is called a global shutter mode. There is a break time TB 1 between a first period P1 and a second period P2.

Accordingly, FIGS. 2-5 illustrate a selection unit which is connected between the floating diffusion region and the output unit, and is configured to reduce dark current that flows into the floating diffusion region, compared to absence of the selection unit between the floating diffusion region and the output unit, according to various embodiments described herein. For example, when the pixel 10-1 of FIG. 4 does not include the second selection unit 31, which may correspond to the second selection transistor 31, dark current will flow from the impurity region 30 to the floating diffusion region 14 of FIG. 2. However, by including the second selection unit 31, the source follower output transistor 21 can convert charges stored in the floating diffusion node FD into an output voltage Vout, without including charge induced by dark current, because the second selection unit 31 is turned off to reduce or prevent the dark current from flowing into the floating diffusion region when accumulated charges are transmitted to the floating diffusion node FD from the photo detector 11. Thus, as shown in FIG. 5, when the transmission gate signal TG is high, the second selection signal SEL2 is low. Other embodiments of a selection unit, which is connected between the floating diffusion region and the output unit, and is configured to reduce dark current that flows into the floating diffusion region, compared to absence of the selection unit between the floating diffusion region and the output unit, will now be described.

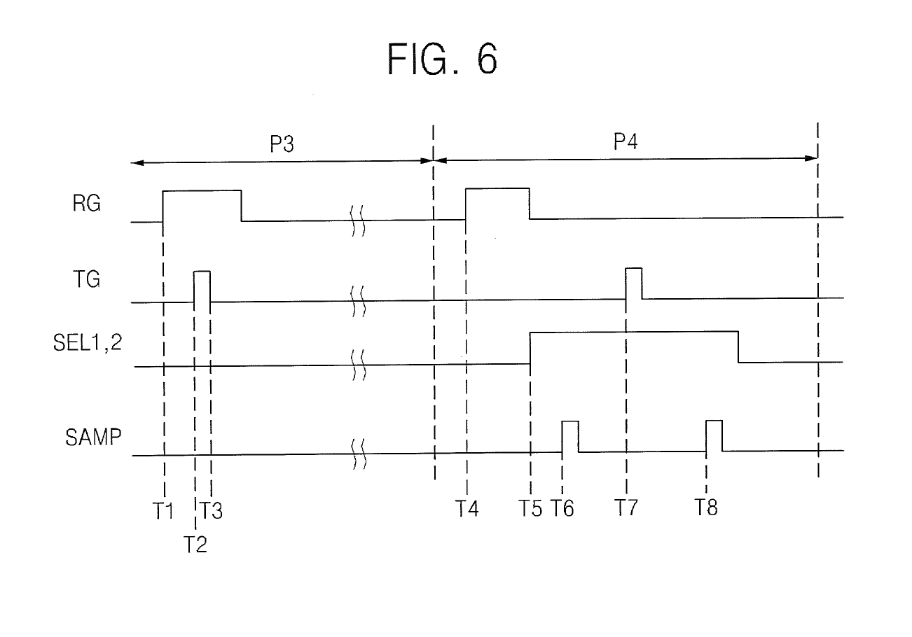

FIG. 6 is a timing diagram of control signals RG, TG, SEL1 and SEL2 for explaining another example embodiment of the pixel illustrated in FIG. 2. Referring to FIGS. 2 and 6, when a reset gate signal RG is applied to the reset gate 19 at a first time point T1, the floating diffusion node FD is reset to a supply voltage VDD.

When a reset gate signal RG is applied to the reset gate 19 and a transmission gate signal TG is applied to the transmission gate 15 at a second time point T2, the photo detector 11 is reset to a supply voltage VDD. The photo detector 11 accumulates charges in response to an incident light from a third time point T3 to a seventh time point T7.

When a reset gate signal RG having a high level is applied to the reset gate 19 at a fourth time point T4, a first selection signal SEL1 is applied to the first selection gate 27 at a fifth time point T5, and a second selection signal SEL2 is applied to the second selection gate 31, the source follower output transistor 21 converts a supply voltage VDD into an output voltage Vout.

The selection gate 27 outputs a pixel signal SAMP having a reset level to the column line 33 at a sixth time point T6. When a transmission gate signal TG is applied to the transmission gate 15 at a seventh time point T7, accumulated charges are transmitted to the floating diffusion node FD from the photo detector 11. The source follower output transistor 21 converts charges stored in the floating diffusion node FD into an output voltage Vout. The first selection gate 27 outputs a pixel signal SAMP having a signal level to the column line 33 at an eighth time point T8.

There is a break time TB 1 between a first period P1 and a second period P2 in FIG. 5, and there is not a break time between a third period P3 and a fourth period P4 in FIG. 6. As illustrated in FIG. 6, when a pixel signal SAMP is output it is called a rolling shutter mode.

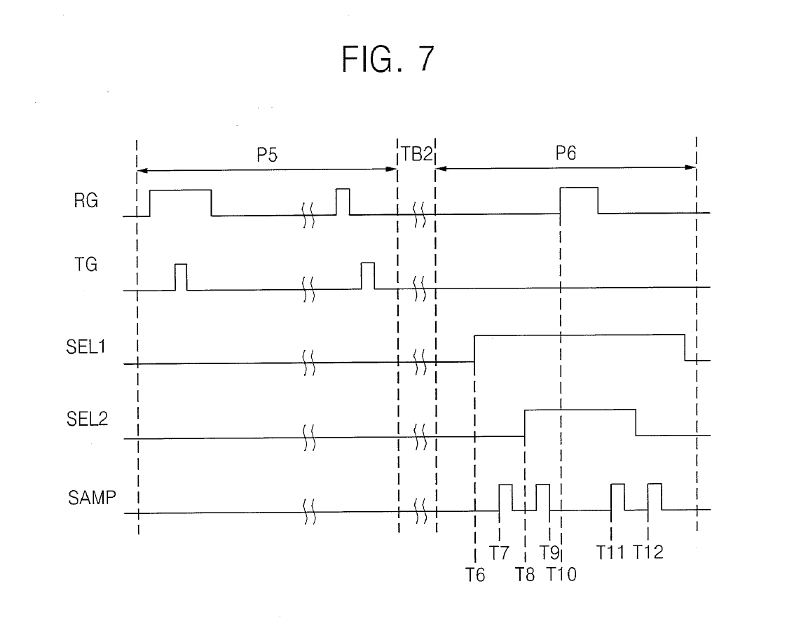

FIG. 7 is a timing diagram of control signals RG, TG, SEL1 and SEL2 for explaining another example embodiment of the pixel illustrated in FIG. 2. A level of each signal RG, TG and SEL1 during a fifth period P5 of FIG. 7 is the same as a level of each signal RG, TG and SEL1 during a first period P1 of FIG. 5, so that explanation for this is not repeated.

Referring to FIGS. 1, 2, 4 and 7, when a first selection signal SEL1 having a high level is applied to the first selection gate 27 at a sixth time point T6, a pixel signal SAMP having a dark current level caused by the contact 32 is output at a seventh time point T7.

When a second selection signal SEL2 having a high level is applied to the second selection gate 31 at an eighth time point T8, a pixel signal SAMP having the dark current level and a signal level is output at a ninth time point T9. When a reset gate signal RG having a high level is applied to the reset gate 19 at a tenth time pint T10, the floating diffusion node FD is reset to a supply voltage VDD.

A pixel signal SAMP which has a reset level for a pixel signal SAMP output from a ninth time point T9 is output at an eleventh time point T11. A pixel signal SAMP which has a reset level for a pixel signal SAMP output at a seventh time point T7 is output at a twelfth time point T12.

Referring to FIG. 1, the CDS block 150 may perform an operation like an equation 1.

E=ABS [(B−C)−(A−D)] [Equation 1]

Here, ‘A’ means a pixel signal SAMP output at a seventh time point T7, ‘B’ means a pixel signal SAMP output at an eighth time point T8, ‘C’ means a pixel signal SAMP output at an eleventh time point T11, ‘D’ means a pixel signal SAMP output at a twelfth time point T12, and ‘E’ means a signal output from the CDS block 150. ‘ABS[ ]’ means an absolute value of a signal.

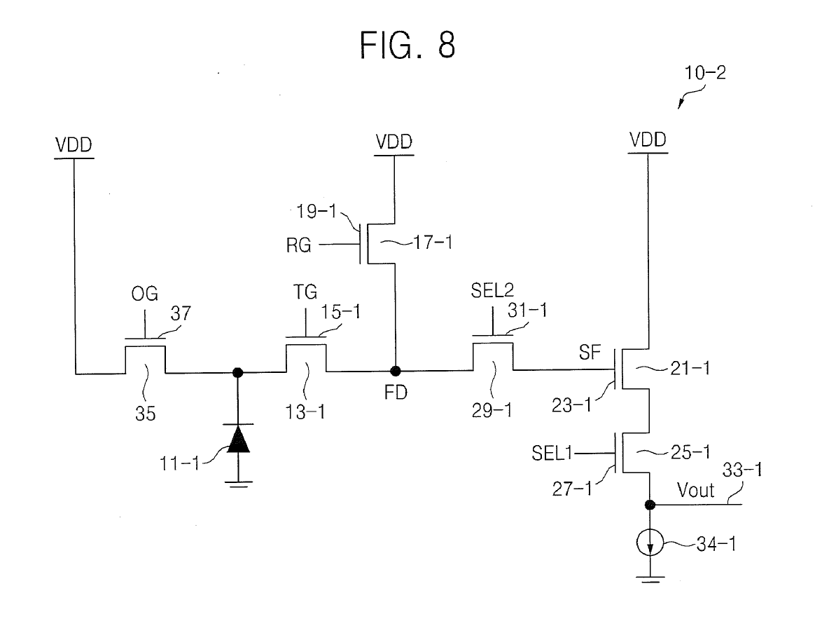

FIG. 8 is a circuit diagram depicting another example embodiment of the pixel embodied in the pixel array illustrated in FIG. 1. Referring to FIGS. 1 and 8, a pixel 10-2 according to another example embodiment of the pixel 10 includes a photo detector 11-1, a transmission transistor 13-1, a reset transistor 17-1, a source follower output transistor 21-1, a first selection transistor 25-1, a second selection transistor 29-1, a current source 34-1 and an overflow transistor 35.

Each element of the pixel 10-2 except for the overflow transistor 35 has an operation and a function similar to each element of the pixel 10-1 illustrated in FIG. 2, so that detailed explanation for this is not repeated. The overflow transistor 35 is connected between a node supplying a supply voltage VDD and the photo detector 11-1. The overflow transistor 35 includes an overflow gate 37. The overflow gate 37 is used to reduce or prevent charges from flowing over the photo detector 11-1. The overflow transistor 35 is activated by an overflow gate signal OG.

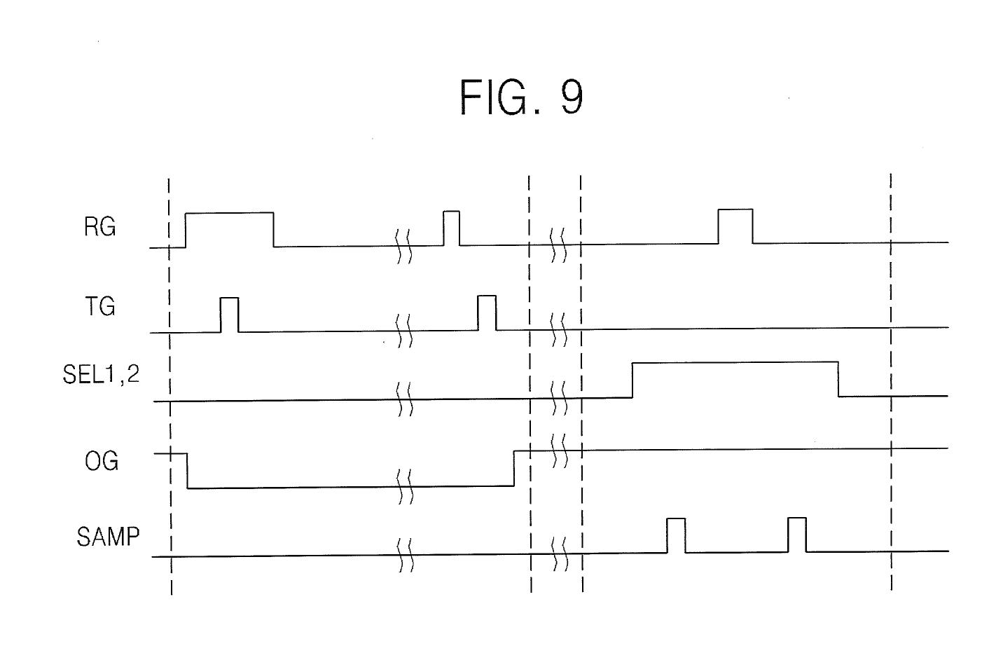

FIG. 9 is a timing diagram of control signals RG, TG, SEL1, SEL2 and OG for explaining an example embodiment of an operation of the pixel illustrated in FIG. 8. Referring to FIGS. 8 and 9, after the photo detector 11-1 accumulates charges in response to an incident light, an overflow gate signal OG having a high level is applied to the overflow gate 37. Accordingly, it may reduce or prevent charges from flowing over the photo detector 11-1.

A level of each signal RG, TG, SEL1 and SEL2 except for an overflow gate signal OG is similar to a level of each signal of FIG. 5, so that detailed explanation for this is not repeated.

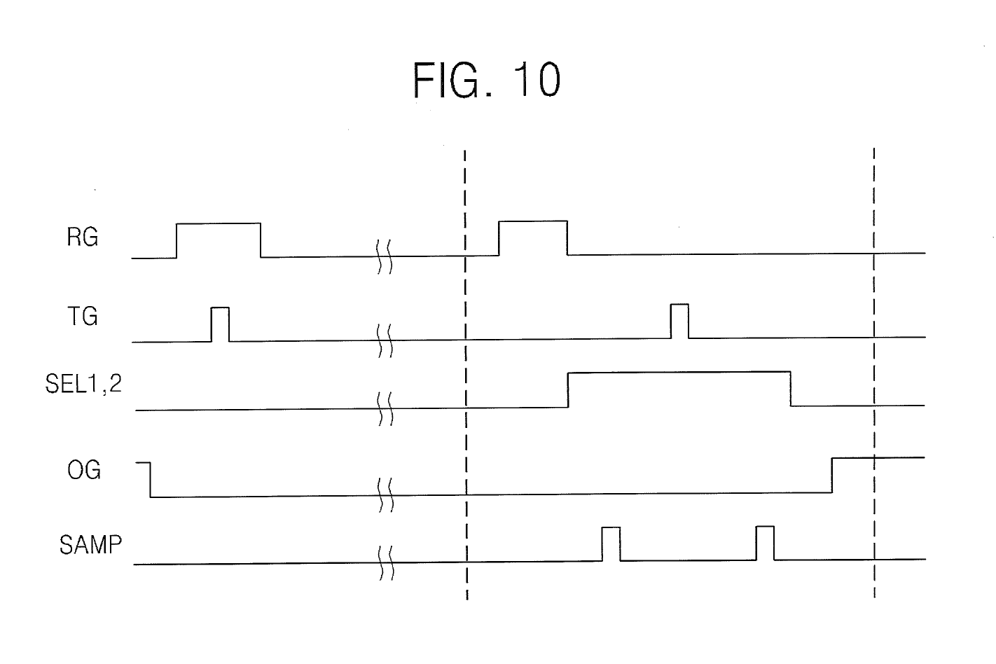

FIG. 10 is a timing diagram of control signals RG, TG, SEL1, SEL2 and OG for explaining another example embodiment of the operation of the pixel illustrated in FIG. 8. Referring to FIGS. 8 and 10, an overflow gate signal OG having a high level is applied to the overflow gate 37 to reduce or prevent accumulated charges from flowing over the photo detector 11-1.

A level of each signal RG, TG, SEL1 and SEL2 of FIG. 10 except for the overflow gate signal OG is similar to a level of each signal of FIG. 6, so that detailed explanation for this is not repeated.

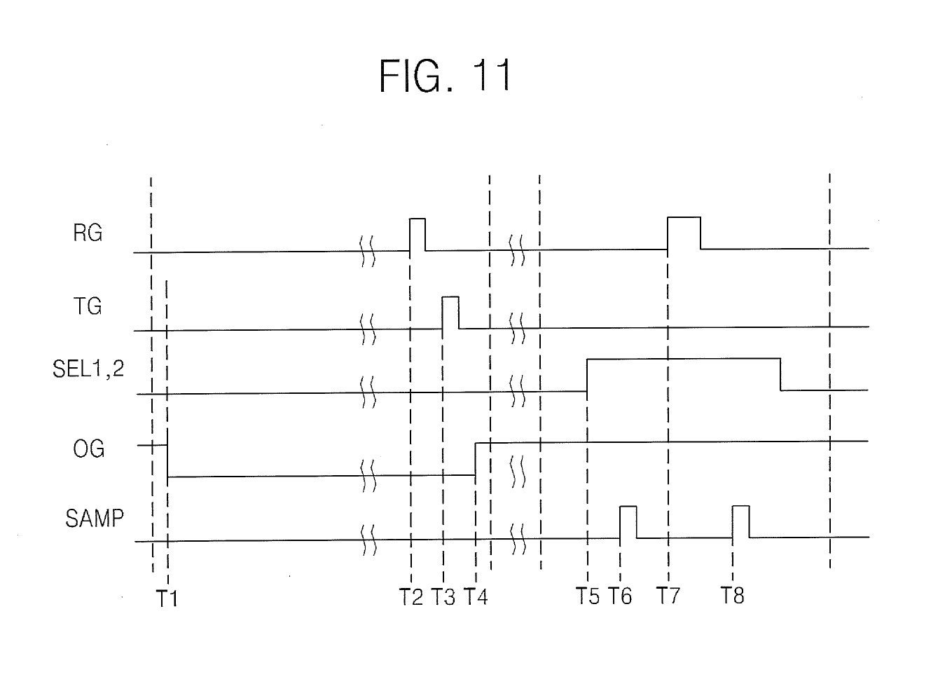

FIG. 11 is a timing diagram of control signals RG, TG, SEL1, SEL2 and OG for explaining still another example embodiment of the operation of the pixel illustrated in FIG. 8. Referring to FIGS. 8 and 11, the photo detector 11-1 accumulates charges in response to an incident light from a first time point T1 to a third time point T3.

When a reset gate signal RG is applied to the reset gate 19-1 at a second time point T2, the floating diffusion node FD is reset to a supply voltage VDD. Accumulated charges are transmitted from the photo detector 11-1 to the floating diffusion node FD at a third time point T3. An overflow gate signal OG having a high level is applied to the overflow gate 37 at a fourth time point T4.

When a first selection signal SEL1 is applied to a first selection gate 27-1 at a fifth time point T5 and a second selection signal SEL2 is applied to a second selection gate 31-1, the source follower output transistor 21-1 converts charges stored in the floating diffusion node FD into an output voltage Vout. A pixel signal SAMP having a signal level is output to the column line 33-1 at a sixth time point T6.

When a reset gate signal RG having a high level is applied to the reset gate 19-1 at a seventh time point T7, the source follower output transistor 21-1 converts a supply voltage VDD into an output voltage Vout. A pixel signal SAMP having a reset level is output to the column line 33-1 at an eighth time point T8.

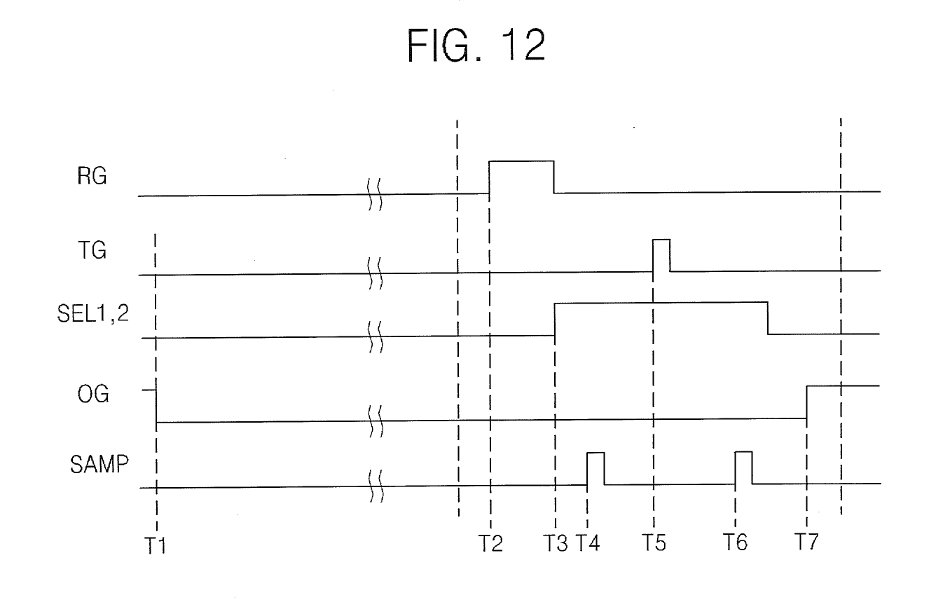

FIG. 12 is a timing diagram of control signals RG, TG, SEL1, SEL2 and OG for explaining still another example embodiment of the operation of the pixel illustrated in FIG. 8. Referring to FIGS. 8 and 12, the photo detector 11-1 accumulates charges in response to an incident light from a first time point T1 to a fourth time point T4.

When a reset gate signal RG is applied to the reset gate 19-1 at a second time point T2, the floating diffusion node FD is reset to a supply voltage.

When a first selection signal SEL1 is applied to the first selection gate 27-1 at a third time point T3 and a second selection signal SEL2 is applied to the second selection gate 31-1, the source follower output transistor 21-1 converts the supply voltage into an output voltage Vout and the selection gate 27-1 outputs a pixel signal SAMP having a reset level to the column line 33-1 at a fourth time point T4.

When a first selection signal SEL1 is applied to the first selection gate 27-1, a second selection signal SEL2 is applied to the second selection gate 31-1, and a transmission gate signal TG is applied to a transmission gate 15-1 at a fifth time point T5, accumulated charges are transmitted from the photo detector 11-1 to the floating diffusion node FD. The source follower output transistor 21-1 converts charges stored in the floating diffusion node FD into an output voltage Vout. The first selection gate 27-1 outputs a pixel signal SAMP having a signal level to the column line 33-1 at a sixth time point T6.

An overflow gate signal OG having a high level is applied to the overflow gate 37 at a seventh time point T7.

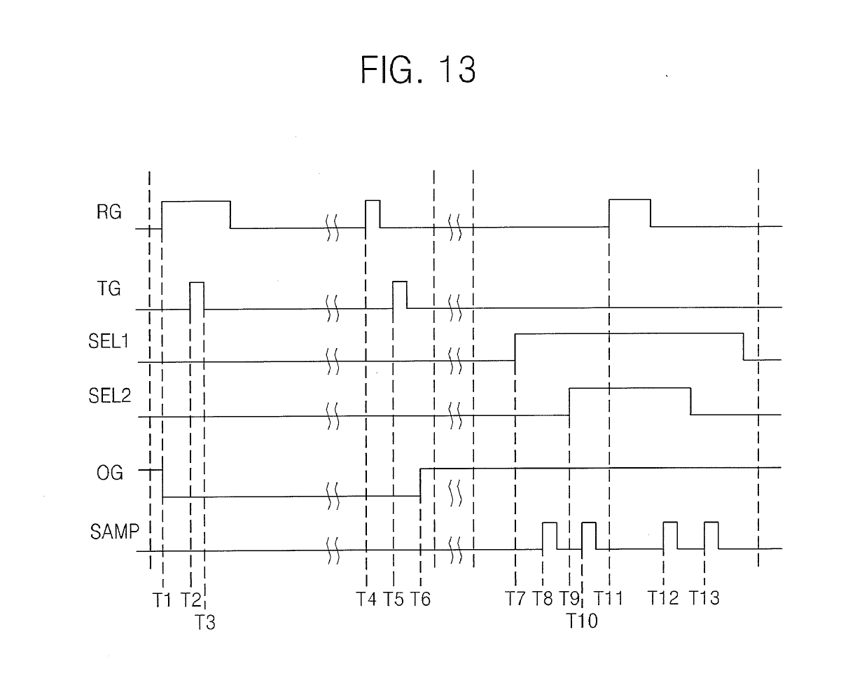

FIG. 13 is a timing diagram of control signals RG, TG, SEL1, SEL2 and OG for explaining still another example embodiment of the operation of the pixel illustrated in FIG. 8. Referring to FIGS. 1, 8 and 13, when a reset gate signal RG is applied to the reset gate 19-1 at a first time point T1, the floating diffusion node FD is reset to a supply voltage VDD.

When a transmission gate signal TG is applied to the transmission gate 15-1 at a second time point T2, the photo detector 11-1 is reset to a supply voltage. The photo detector 11-1 accumulates charges in response to an incident light from a third time point T3 to a fifth time point T5.

When a reset gate signal RG is applied to the reset gate 19-1 at a fourth time point T4, the floating diffusion node FD is reset to a supply voltage. When a transmission gate signal TG is applied to the transmission gate 15-1 at a fifth time point T5, accumulated charge are transmitted from the photo detector 11-1 to the floating diffusion node FD.

An overflow gate signal OG having a high level is applied to the overflow gate 37 at a sixth time point T6. When a first selection signal SEL1 having a high level is applied to the first selection gate 27-1 at a seventh time point T7, a pixel signal SAMP having a dark current level is output at an eighth time point T8. When a second selection signal SEL2 having a high level is applied to the second selection gate 31-1 at a ninth time point T9, a pixel signal SAMP having the dark current level and a signal level is output at a tenth time point T10.

When a reset gate signal RG having a high level is applied to the reset gate 19-1 at an eleventh time point T11, the floating diffusion node FD is reset to the supply voltage. A pixel signal SAMP having a reset level for a pixel signal SAMP output at a tenth time point T10 is output at a twelfth time point T12. A pixel signal SAMP having a reset level for a pixel signal output from an eighth time point T8 is output at a thirteenth time point T13.

The CDS block 150 outputs a signal by using an equation 1 which is explained referring to FIG. 7.

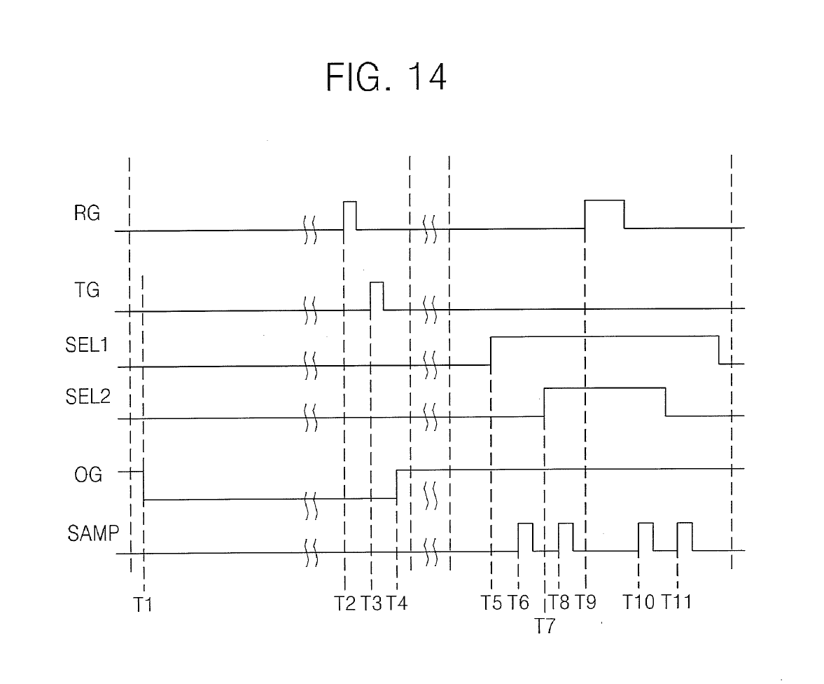

FIG. 14 is a timing diagram of control signals RG, TG, SEL1, SEL2, and OG for explaining still another example embodiment of the operation of the pixel illustrated in FIG. 8. Referring to FIGS. 1, 8 and 14, the photo detector 11-1 accumulates charges in response to an incident light from a first time point T1 to a third time point T3.

When a reset gate signal RG is applied to the reset gate 19-1 at a second time point T2, the floating diffusion node FD is reset to a supply voltage. When a transmission gate signal TG is applied to the transmission gate 15-1 at a third time point T3, accumulated charges are transmitted from the photo detector 11-1 to the floating diffusion node FD. An overflow gate signal OG having a high level is applied to the overflow gate 37 at a fourth time point T4.

When a first selection signal SEL1 having a high level is applied to the first selection gate 27-1 at a fifth time point T5, a pixel signal SAMP having a dark current level is output at a sixth time point T6. When a second selection signal SEL2 having a high level is applied to the second selection gate 31-1 at a seventh time point T7, a pixel signal SAMP having the dark current level and a signal level is output at an eighth time point T8.

When a reset gate signal RG having a high level is applied to the reset gate 19-1 at a ninth time point T9, the floating diffusion node FD is reset to the supply voltage. A pixel signal SAMP having a reset level for a pixel signal SAMP output at an eighth time point T8 is output at a tenth time point T10. A pixel signal SAMP having a reset level for a pixel signal SAMP output at a sixth time point T6 is output at an eleventh time point T11.

The CDS block 150 outputs a signal by using an equation 1 which is explained referring to FIG. 7.

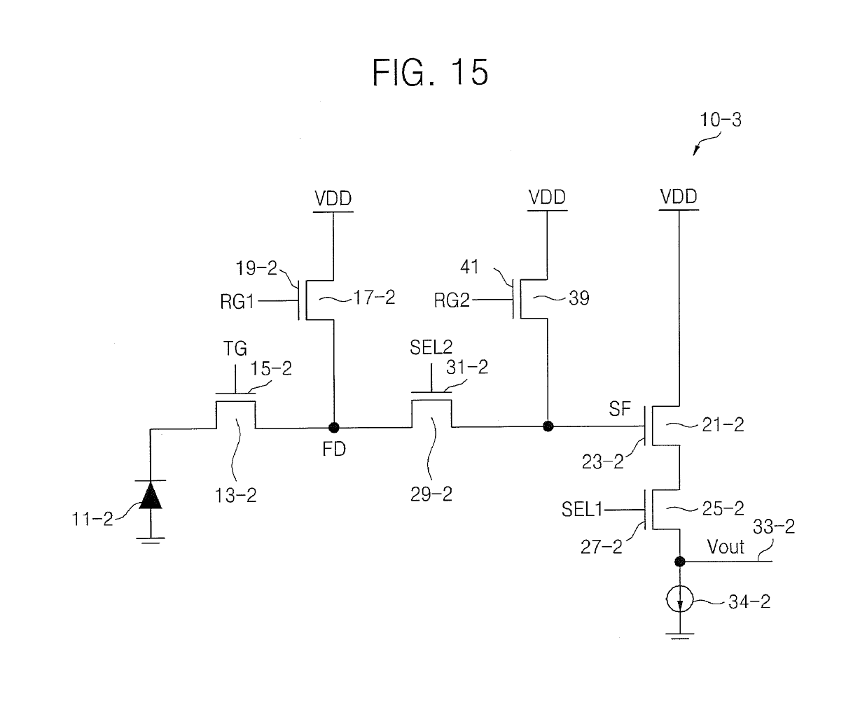

FIG. 15 is a circuit diagram depicting still another example embodiment of a pixel embodied in the pixel array illustrated in FIG. 1. Referring to FIGS. 1 and 15, a pixel 10-3 according to still another example embodiment of the pixel 10 includes a photo detector 11-2, a transmission transistor 13-2, a first reset transistor 17-2, a second reset transistor 39, a source follower output transistor 21-2, a first selection transistor 25-2, a second selection transistor 29-2 and a current source 34-2.

Each configuration element of the pixel 10-3 except for the second reset transistor 39 has an operation and a function similar to a configuration element of the pixel 10-1 illustrated in FIG. 2, so that explanation for this is not repeated.

The second reset transistor 39 is connected between a supply voltage node VDD and a source follower gate 23-2. The second reset transistor 39 includes a second reset gate 41. The second reset transistor 39 is activated by a second reset gate signal RG2. For example, when the second reset gate signal RG2 is at a high level, the second reset transistor 39 may be activated.

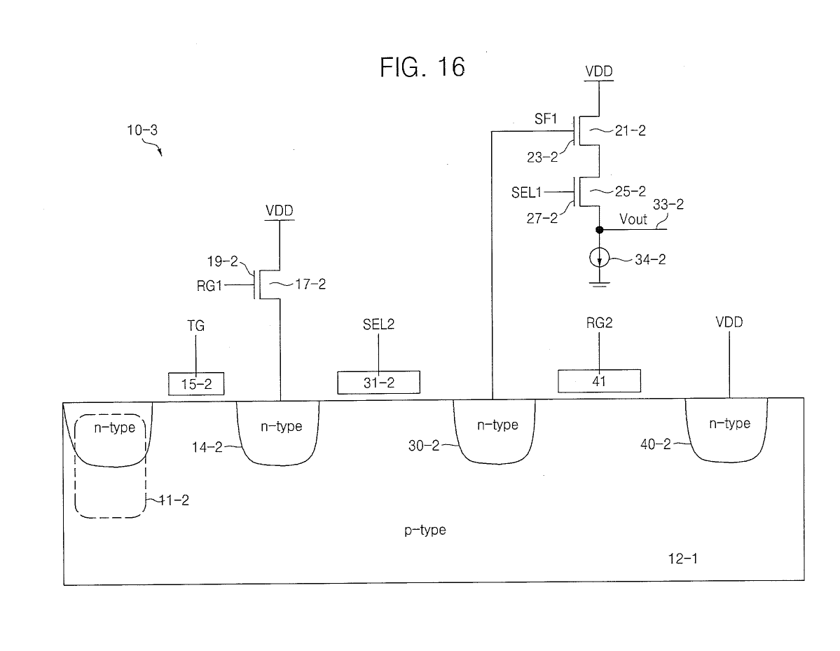

FIG. 16 is a cross-sectional diagram of the pixel illustrated in FIG. 15. Referring to FIGS. 15 and 16, each configuration element 15-2, 19-2, 23-2, 27-2, 31-2 and 41 may be arranged on a substrate 12-1. The substrate 12-1 may be a p-type epitaxial region in a single element and/or compound semiconductor substrate and/or a semiconductor layer. According to an example embodiment, the substrate 12-1 may further include an insulator (not shown). The photo detector 11-2, the floating diffusion region 14-2, a first impurity region 30-2 and a second impurity region 40-2 are formed by implanting an n-type dopant on the substrate 12-1. The photo detector 11-2 includes a n-type region and a p-type epitaxial region. The floating diffusion region 14-2 is a charge storage region of the floating diffusion region FD. The floating diffusion region 14-2 includes a n-type region.

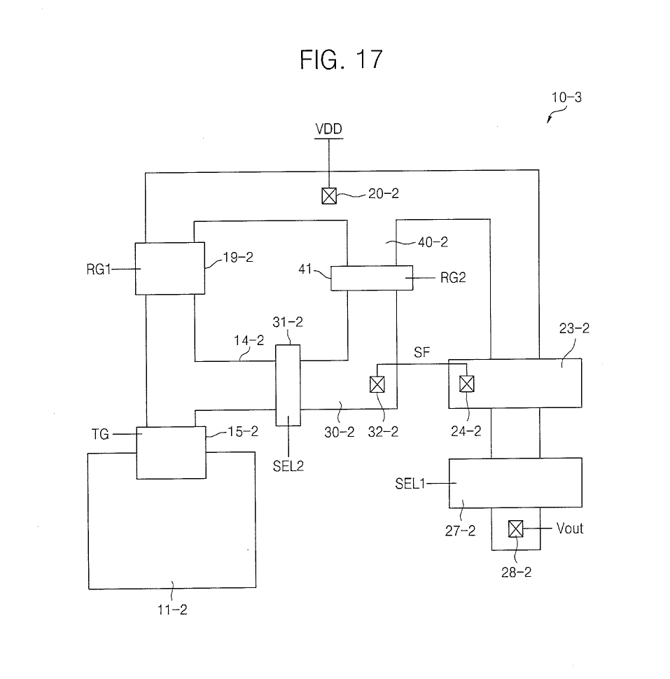

FIG. 17 is a top view of the pixel illustrated in FIG. 15. Referring to FIGS. 15 to 17, the first impurity region 30-2 includes a contact 32-2 for applying a source follower gate signal SF to the source follower gate 23-2. The contact 32-2 is connected to a source follower gate contact 24-2 of the source follower gate 23-2. A second selection gate 31-2 reduces or prevents a dark current occurred by the contact 32-2 from being flowed in the floating diffusion region 14-2 from an impurity region 30. The second impurity region 40-2 includes a supply voltage contact 20-2 to get a supply voltage applied. An output voltage Vout is output through an output voltage contact 28-2.

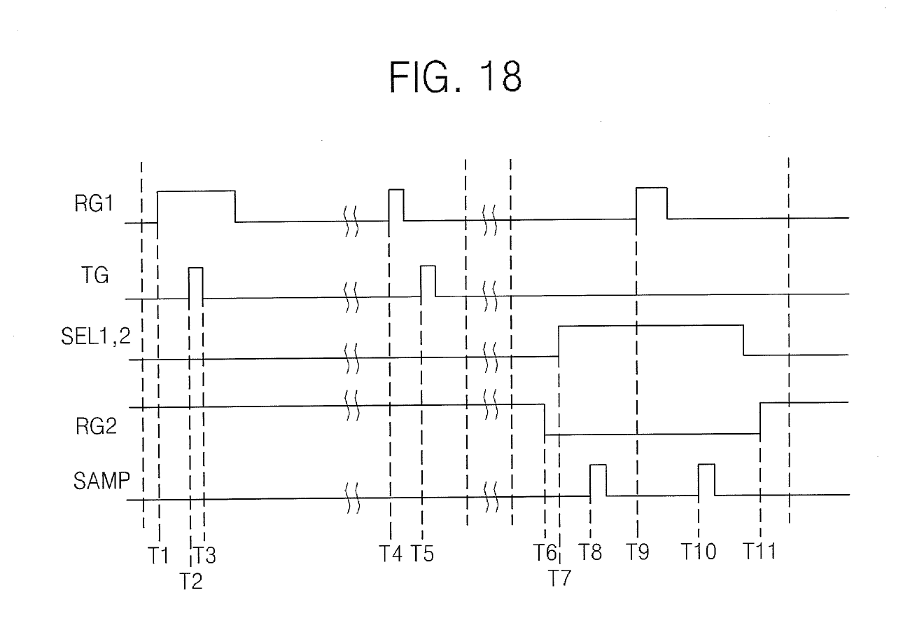

FIG. 18 is a timing diagram depicting control signals RG, TG, SEL1, SEL2 and 002 for explaining an example embodiment of the operation of the pixel illustrated in FIG. 15, Referring to FIGS. 15 and 18, when a first reset gate signal RG1 is applied to a first reset gate 19-2 at a first time point T1, the floating diffusion node FD is reset to a supply voltage.

When a first reset gate signal RG1 is applied to the first reset gate 19-2 and a transmission gate signal TG is applied to a transmission gate 15-2 at a second tie point T2, the photo detector 11-2 is reset to the supply voltage. The photo detector 11-2 accumulates charges in response to an incident light from a third time point T3 to a fifth time point T5.

When a first reset gate signal RG1 is applied to the first reset gate 19-2 at a fourth time point T4, the floating diffusion node FD is reset to the supply voltage. When a transmission gate signal TG is applied to the transmission gate 15-2 at a fifth time point T5, accumulated charges are transmitted from the photo detector 11-2 to the floating diffusion node FD. A second reset gate signal RG2 having a low level is applied to a second reset gate 41 at a sixth time point T6.

When a first selection signal SEL1 is applied to the first selection gate 27-2 at a seventh time point T7 and a second selection signal SEL2 is applied to a second selection gate 31-2, the source follower output transistor 21-2 converts charges stored in the floating diffusion node (FD) into an output voltage Vout. A pixel signal SAMP having a signal level is output to the column line 33-2 at an eighth time point T8. The signal level is a level corresponding to a level of the output voltage Vout.

When a first reset gate signal RG1 having a high level is applied to the first reset gate 19-2 at a ninth time point T9, the source follower output transistor 21-2 outputs an output voltage Vout corresponding to a supply voltage VDD, A pixel signal SAMP having a reset level is output to the column line 33-2 at a tenth time point T10. The reset level is a level corresponding to a level of the output voltage Vout. A second reset gate signal RG2 having a high level is applied to the second reset gate 41 at an eleventh time point T11.

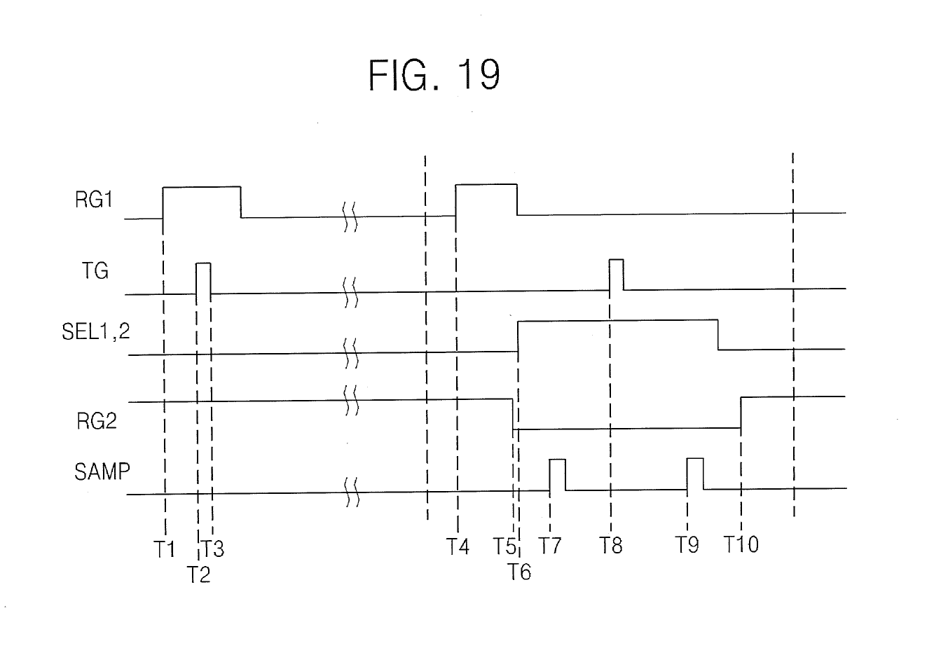

FIG. 19 is a timing diagram depicting control signals RG1, TG, SEL1, SEL2 and RG2 for explaining another example embodiment of the operation of the pixel illustrated in FIG. 15. Referring to FIGS. 15 and 19, when a first reset gate signal RG1 is applied to the first reset gate 19-2 at a first time point T1, the floating diffusion node FD is reset to a supply voltage.

When a first reset gate signal RG1 is applied to the first reset gate 19-2 and a transmission gate signal TG is applied to the transmission gate 15-2 at a second time point T2, the photo detector 11-2 is reset to the supply voltage.

The photo detector 11-2 accumulates charges in response to an incident light from a third time point T3 to an eighth time point T8. A first reset gate signal RG1 having a high level is applied to the first reset gate 19-2 at a fourth time point T4. A second reset gate signal RG2 having a low level is applied to the second reset gate 41 at a fifth time point T5. A first selection signal SEL1 is applied to the first selection gate 27-2 at a sixth time point T6 and a second selection signal SEL2 is applied to the second selection gate 31-2.

A pixel signal SAMP having a reset level is output to the column line 33-2 at a seventh time point T7. The reset level is a level corresponding to a level of the output voltage Vout. When a transmission gate signal TG is applied to the transmission gate 15-2 at an eighth time point T8, accumulated charges are transmitted from the photo detector 11-2 to the floating diffusion node FD.

The source follower output transistor 21-2 converts charges stored in the floating diffusion node FD into an output voltage Vout at a ninth time point T9. A pixel signal SAMP having a signal level is output to the column line 33-2 at a ninth time point T9. The signal level is a level corresponding to a level of the output voltage Vout. A second reset gate signal RG2 having a high level is applied to the second reset gate 41 at a tenth time point T10.

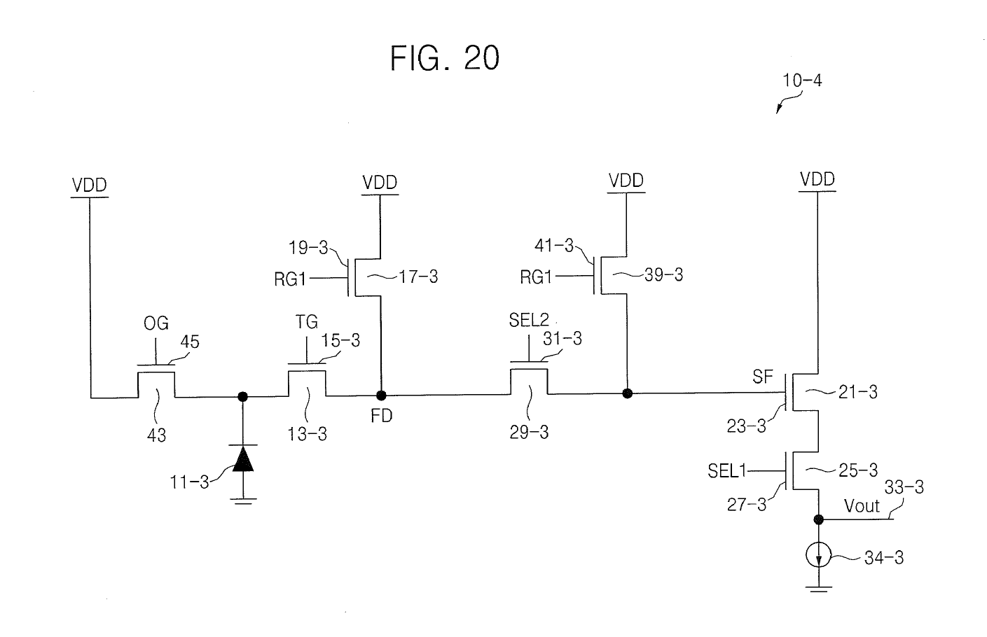

FIG. 20 is a circuit diagram depicting still another example embodiment of the pixel embodied in the pixel array illustrated in FIG. 1. Referring to FIGS. 1 and 20, a pixel 10-4 according to still another example embodiment of the pixel 10 includes a photo detector 11-3, a transmission transistor 13-3, a first reset transistor 17-3, a second reset transistor 39-3, a source follower output transistor 21-3, a first selection transistor 25-3, a second selection transistor 29-3, a current source 34-3 and an overflow transistor 43-3.

Each configuration element of the pixel 10-4 except for an overflow transistor 43 has an operation and a function similar to a configuration element of the pixel 10-3 illustrated in FIG. 15, so that explanation for this is not repeated.

The overflow transistor 43 is connected between a supply voltage node VDD and the photo detector 11-3. The overflow transistor 43 includes an overflow gate 45. The overflow gate 45 is used to reduce or prevent charges from flowing over the photo detector 11-3. The overflow transistor 43 is activated by an overflow gate signal OG.

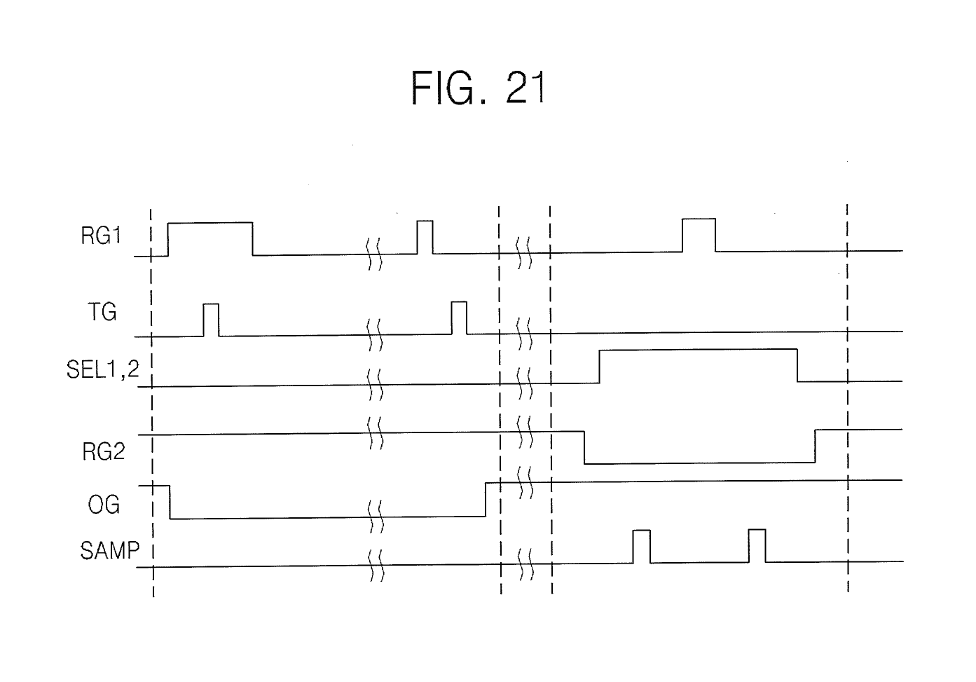

FIG. 21 is a timing diagram depicting control signals RG1, TG, SEL1, SEL2, RG2 and OG for explaining an example embodiment of the operation of the pixel illustrated in FIG. 20.

Referring to FIGS. 20 and 21, an overflow gate signal OG having a high level is applied to an overflow gate 45 to reduce or prevent accumulated charges from flowing over the photo detector 11-3. A level of each signal RG1, TG, SEL1, SEL2 and RG2 of FIG. 21 except for an overflow gate signal OG is similar to a level of each signal of FIG. 18. Accordingly, explanation for each signal is not repeated.

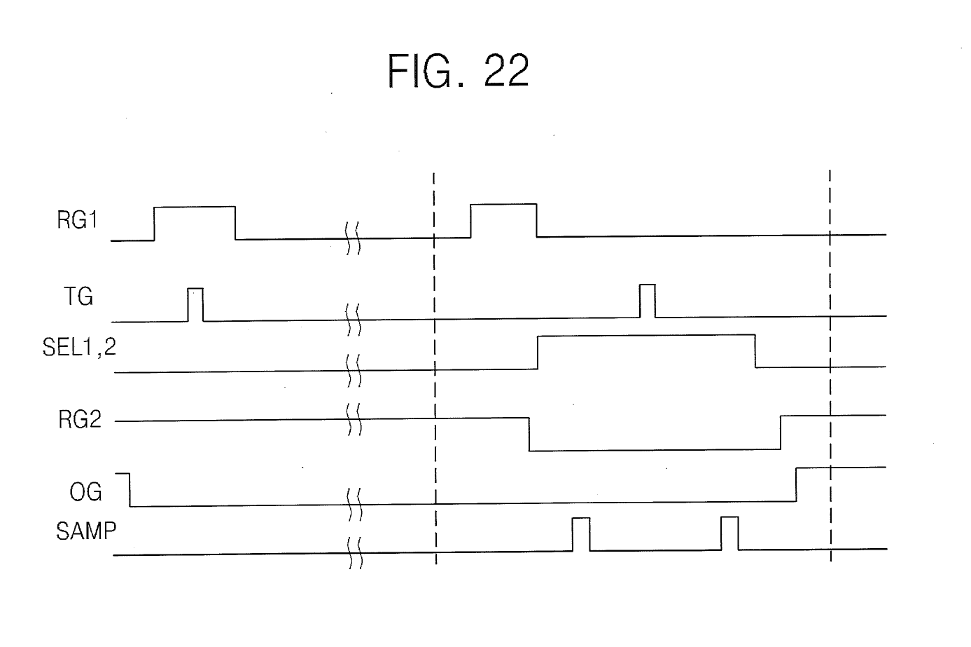

FIG. 22 is a timing diagram depicting control signals RG1, TG, SEL1, SEL2, RG2 and OG for explaining another example embodiment of the operation of the pixel illustrated in FIG. 20.

Referring to FIGS. 20 and 22, an overflow gate signal OG having a high level is applied to the overflow gate 45 to reduce or prevent accumulated charges from flowing over the photo detector 11-3. A level of each signal RG1, TG, SEL1, SEL2 and RG2 of FIG. 22 except for an overflow gate signal OG is similar to a level of each signal of FIG. 19. Accordingly, explanation for each signal is not repeated.

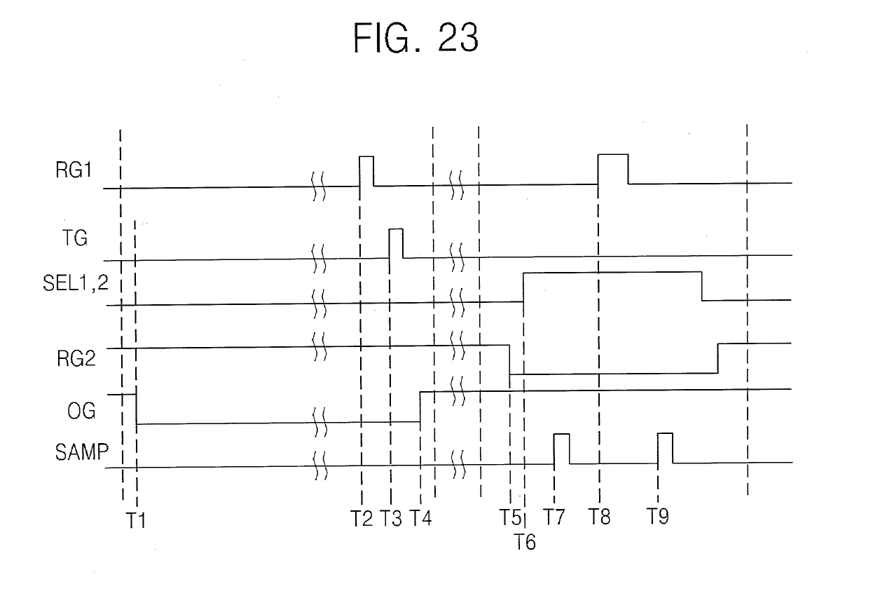

FIG. 23 is a timing diagram depicting control signals RG1, TG, SEL1, SEL2, RG2 and OG for explaining another example embodiment of the operation of the pixel illustrated in FIG. 20.

Referring to FIGS. 20 and 23, the photo detector 11-3 accumulates charges in response to an incident light from a first time point T1 to a third time point T3. When a reset gate signal RG is applied to the reset gate 19-3 at a second time point T2, the floating diffusion node FD is reset to a supply voltage VDD.

Accumulated charges are transmitted from the photo detector 11-3 to the floating diffusion node FD at a third time point T3. An overflow gate signal OG having a high level is applied to an overflow gate 45 at a fourth time point T4.

A second reset gate signal RG2 having a low level is applied to the second reset gate 41-3 at a fifth time point T5. When a first selection signal SEL1 is applied to the first selection gate 27-3 at a sixth time point T6 and a second selection signal SEL2 is applied to the second selection gate 31-3, the source follower output transistor 21-3 converts charges stored in the floating diffusion node FD into an output voltage Vout. A pixel signal SAMP having a signal level is output to the column line 33-3 at a seventh time point T7.

When a reset gate signal RG having a high level is applied to the reset gate 19-3 at an eighth time point T8, the source follower output transistor 21-3 outputs an output voltage Vout corresponding to the supply voltage. A pixel signal SAMP having a reset level is output to the column line 33-3 at a ninth time point T9.

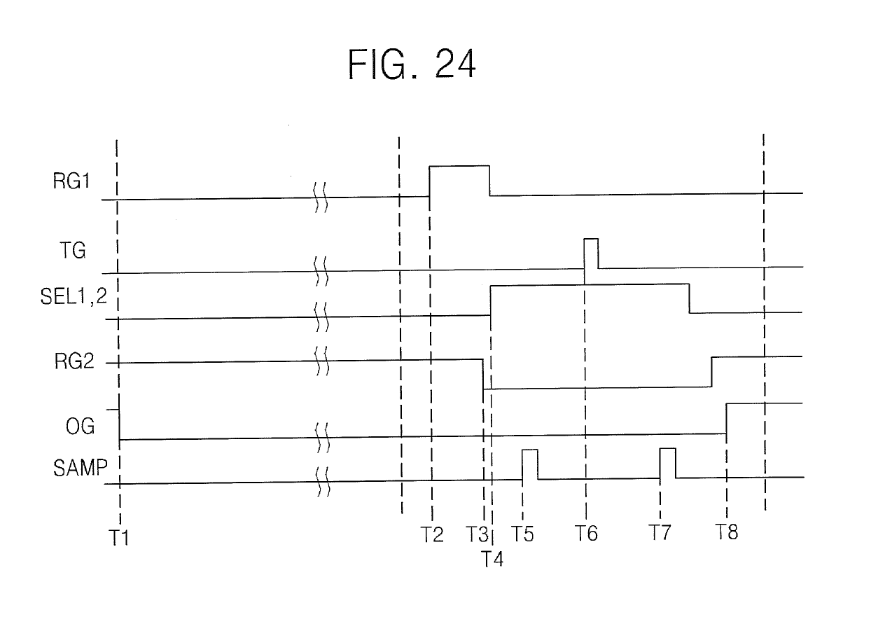

FIG. 24 is a timing diagram depicting control signals RG1, TG, SEL1, SEL2, RG2 and OG for explaining still another example embodiment of the operation method of the pixel illustrated in FIG. 20. Referring to FIGS. 20 and 24, the photo detector 11-3 accumulates charges in response to an incident light from a first time point T1 to a sixth time point T6.

When a first reset gate signal RG1 is applied to the first reset gate 19-3 at a second time point T2, the floating diffusion node FD is reset to a supply voltage VDD. A second reset gate signal RG2 having a low level is applied to the second reset gate 41-3 at a third time point T3.

When a first selection signal SEL1 is applied to the first selection gate 27-3 at a fourth time point T4 and a second selection signal SEL2 is applied to the second selection gate 31-3, the source follower output transistor 21-3 converts charges stored in the floating diffusion node FD into an output voltage Vout corresponding to the supply voltage and the first selection gate 27-3 outputs a pixel signal SAMP having a reset level to the column line 33-1 at a fifth time point T5.

When a transmission gate signal TG is applied to the transmission gate 15-3 at a sixth time point T6, accumulated charges are transmitted from the photo detector 11-3 to the floating diffusion node FD. The source follower output transistor 21-3 converts charges stored in the floating diffusion node FD into an output voltage Vout. The first selection gate 27-3 outputs a pixel signal SAMP having a signal level to the column line 33-3 at a seventh time point T7. An overflow gate signal OG having a high level is applied to the overflow gate 45 at an eighth time point T8.

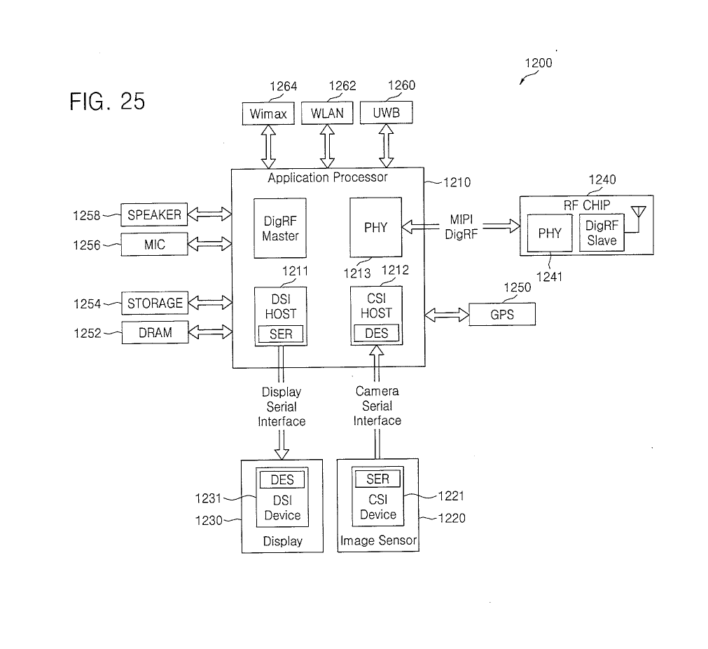

FIG. 25 is a block diagram depicting another example embodiment of the image processing device including the pixel illustrated in FIGS. 2, 8, 15 and/or 20. Referring to FIG. 25, an image processing device 1200 may be embodied in an image processing device, e.g., a portable device such as a personal digital assistant (PDA), a portable media player (PMP), a cellular phone, a smart phone or a tablet PC, which may use or support a mobile industry processor interface (MIPI®). The image processing device also may be a non-portable device.

The image processing device 1200 includes an application processor 1210, an image sensor 1220 and a display 1230.

A camera serial interface (CSI) host 1212 embodied in the application processor 1210 may perform a serial communication with a CSI device 1221 of the image sensor 1220 through a camera serial interface (CSI). According to an example embodiment, a de-serializer (DES) may be embodied in a CSI host 1212 and a serializer (SER) may be embodied in the CSI device 1221.

The image sensor 1220 may mean an image sensor including a pixel 10-1, 10-2, 10-3 and/or 10-4 illustrated in FIG. 2, 8, 15 or 20.

A display serial interface (DSI) host 1211 embodied in the application processor 1210 may perform a serial communication with a DSI device 1231 of the display 1230 through a display serial interface. According to an example embodiment, a serializer (SER) may be embodied in the DSI host 1211 and a de-serializer (DES) may be embodied in the DSI device 1231.

The image processing device 1200 may further include a RF chip 1240 which may communicate with the application processor 1210. A PHY 1213 of the image processing device 1200 and a PHY 1241 of a RF chip 1240 may transmit or receive data according to MIPI DigRF.

The image processing device 1200 may include a GPS receiver 1250, a memory 1252 like a dynamic random access memory (DRAM), a data storage device 1254 embodied in a non-volatile memory like a NAND flash memory, a mike 1256, or a speaker 1258. In addition, the image processing device 1200 may communicate with an external device by using at least a communication protocol (or a communication standard), e.g., a ultra-wideband (UWB) 1260, a wireless LAN (WLAN) 1262, a worldwide interoperability for microwave access (WiMAX) 1264 or a long term evolution (LTE™: not shown).

A transistor of the present inventive concepts may be called a unit.

An image sensor of the present inventive concepts and a portable device having the same may reduce a noise of an image output from a pixel by reducing or preventing a dark current from flowing in a floating diffusion region.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

While the present invention has been particularly shown and described with reference to exemplary embodiments thereof, it will be understood by those of ordinary skill in the art that various changes in forms and details may be made therein without departing from the spirit and scope of the present invention as defined by the following claims.

What is claimed is:

1. An image sensor comprising:
a photo detector configured to accumulate charges in response to an incident light;
a floating diffusion node;
a first reset unit responsive to a first reset gate signal, and which is connected between a supply voltage node and the floating diffusion node;
a transmission unit configured to transmit accumulated charges from the photo detector to the floating diffusion node in response to a transmission gate signal;
an output unit configured to convert charges stored in the floating diffusion node into an output voltage;
a first selection unit configured to output the output voltage in response to a first selection gate signal; and
a second selection unit responsive to a second selection gate signal, and which is connected between the floating diffusion node and the output unit.

2. The image sensor of claim 1, further comprising a row driver configured to output the first reset gate signal, the transmission gate signal, the first selection gate signal and the second selection gate signal.

3. The image sensor of claim 2, wherein a phase of the first selection gate signal is the same as a phase of the second selection gate signal.

4. The image sensor of claim 2, wherein a phase of the first selection gate signal leads a phase of the second selection gate signal.

5. The image sensor of claim 2, further comprising a second reset unit which is connected between the supply voltage node and the output unit.

6. The image sensor of claim 5, wherein the row driver is further configured to output a second reset gate signal having a low level to control the second reset unit when each of the first selection gate signal and the second selection gate signal has a high level.

7. The image sensor of claim 2, further comprising an overflow unit which is connected between the supply voltage node and the photo detector and is configured to reduce the charges from flowing over the photo detector.

8. The image sensor of claim 7, wherein the row driver is further configured to output an overflow gate signal having a high level to reduce the charges from flowing over the photo detector.

9. An imaging device comprising:
an image sensor; and
a display configured to display image data processed by the image sensor,
wherein the image sensor comprises:
a photo detector configured to accumulate charges in response to an incident light;
a floating diffusion node;
a first reset unit which is connected between a supply voltage node and the floating diffusion node in response to a first reset gate signal;
a transmission unit configured to transmit accumulated charges from the photo detector to the floating diffusion node in response to a transmission gate signal;
an output unit configured to convert charges stored in the floating diffusion node into an output voltage;
a first selection unit configured to output the output voltage selectively in response to a first selection gate signal; and
a second selection unit which is connected between the floating diffusion node and the output unit in response to a second selection gate signal.

10. The device of claim 9, wherein the image sensor further comprises a row driver configured to output the first reset gate signal, the transmission gate signal, the first selection gate signal and the second selection gate signal.

11. The device of claim 10, wherein a phase of the first selection gate signal is the same as a phase of the second selection gate signal.

12. The device of claim 10, wherein a phase of the first selection gate signal leads a phase of the second selection gate signal.

13. The device of claim 10, wherein the image sensor further comprises a second reset unit connected between the supply voltage node and the source follower output unit.

14. The device of claim 13, wherein the row driver is further configured to output a second reset gate signal having a low level to control the second reset unit when each of the first selection gate signal and the second selection gate signal has a high level.

15. The device of claim 9, wherein the image sensor further comprises an overflow unit connected between the supply voltage node and the photo detector.

16. An image sensor comprising:
a photo detector configured to accumulate charges in response to an incident light;
a floating diffusion region;
a reset unit responsive to a reset gate signal, and which is connected between a supply voltage node and the floating diffusion region;
a transmission unit configured to transmit accumulated charges from the photo detector to the floating diffusion region in response to a transmission gate signal;
an output unit configured to convert charges stored in the floating diffusion region into an output voltage; and
a selection unit which is connected between the floating diffusion region and the output unit, and is configured to reduce dark current that flows into the floating diffusion region, compared to absence of the selection unit between the floating diffusion region and the output unit.

17. The image sensor of claim 16 wherein the selection unit is configured to prevent dark current from flowing into the floating diffusion region.

18. The image sensor of claim 17, further comprising an overflow unit which is connected between the supply voltage node and the photo detector and is configured to reduce charges from flowing over the photo detector.

19. The image sensor of claim 16 in combination with a digital signal processor configured to process image data from the image sensor.

20. The image sensor of claim 19 in further combination with a display that is configured to display the image data that is processed.
